(19) United States
(12) Patent Application Publication
(10) Pub. No.: US 2026/0213146 A1
(43) Pub. Date: Jul. 23, 2026

(54) SUBSTRATE PROCESSING DEVICE INCLUDING OPTICAL SYSTEMS AND METHOD OF OPERATING THE SAME

(71) Applicant: SAMSUNG ELECTRONICS CO., LTD., Suwon-si (KR)

(72) Inventors: JISOO OH, Suwon-si (KR); Ki-IL KIM, Suwon-si (KR); Changbea PARK, Suwon-si (KR); Kyungyub JEON, Suwon-si (KR)

(73) Assignee: SAMSUNG ELECTRONICS CO., LTD., Suwon-si (KR)

(21) Appl. No.: 19/445,888

(22) Filed: Jan. 12, 2026

(30) Foreign Application Priority Data
Jan. 14, 2025 (KR) 10-2025-0005657

(51) Int. Cl. H01J 37/32; G01N 21/25; G01N 21/95; H10P 72/00

(52) U.S. Cl. CPC H01J 37/32972; G01N 21/255; G01N 21/9501; H01J 37/3244; H10P 72/0604; H01J 2237/334

(57) ABSTRACT

A substrate processing device may include: a chamber including a processing space; a stage inside the processing space, the stage configured to have a substrate thereon, and an upper surface of the stage includes points that are spaced apart from each other; and optical systems configured to respectively radiate incident light toward the points on the upper surface of the stage, while the substrate is on the stage, and receive reflected light generated from the incident light.

### CROSS-REFERENCE TO RELATED APPLICATION

This application claims priority under 35 U.S.C. § 119 to Korean Patent Application No. 10-2025-0005657, filed on Jan. 14, 2025, in the Korean Intellectual Property Office, the disclosure of which is incorporated by reference herein in its entirety.

### BACKGROUND

### 1. Field

Embodiments of the disclosure described herein relate to a substrate processing device and a method of operating the same, more particularly, relate to a substrate processing device capable of identifying process distribution and a method of operating the same.

### 2. Description of Related Art

A semiconductor element may be manufactured by various manufacturing processes. While some semiconductor manufacturing processes are performed, the process may be performed at different speeds at various points of a substrate, and thus process distribution may be generated. When the process distribution is degraded, a yield and productivity of a semiconductor process may decrease. However, as a design rule of the semiconductor element is gradually reduced, the process distribution is becoming increasingly difficult to improve. Accordingly, semiconductor manufacturing equipment that may monitor a progress situation of the process at each point of the substrate while performing the semiconductor process and improve the process distribution has been researched.

### SUMMARY

Embodiments of the disclosure provide a substrate processing device capable of improving a process distribution, and a method of operating the same.

Embodiments of the disclosure provide a substrate processing device capable of monitoring a progress state in real time during a semiconductor process, and a method of operating the same.

Embodiments of the disclosure provide a substrate processing device capable of monitoring a progress state of a process at a plurality of points of a substrate, and a method of operating the same.

Embodiments of the disclosure provide a substrate processing device capable of monitoring an initial state of a substrate before a semiconductor process, and a method of operating the same.

Embodiments of the disclosure provide a substrate processing device capable of improving process distribution through self-feedback control, and a method of operating the same.

Embodiments of the disclosure provide a substrate processing device capable of calculating improved process variables, and a method of operating the same.

According to an aspect of the disclosure, a substrate processing device may include: a chamber including a processing space; a stage inside the processing space, the stage configured to have a substrate thereon, and an upper surface of the stage includes points that are spaced apart from each other; and optical systems configured to respectively radiate incident light toward the points on the upper surface of the stage, while the substrate is on the stage, and receive reflected light generated from the incident light.

According to an aspect of the disclosure, a substrate processing device may include: a chamber including a processing space; a stage inside the processing space, the stage configured to have a substrate thereon; optical passages above the stage, the optical passages being laterally spaced apart from each other; and optical systems configured to: radiate incident light into the processing space through the optical passages; and receive, through the optical passages, reflected light generated inside the processing space based on the incident light.

According to an aspect of the disclosure, a substrate processing device may include: a stage configured to have a substrate thereon; optical systems configured to respectively radiate incident light toward points on an upper surface of the substrate on the stage, and receive reflected light generated from the incident light; and a control system configured to calculate surface data of the points of the substrate based on the reflected light.

### BRIEF DESCRIPTION OF DRAWINGS

The above and other aspects and features of embodiments of the disclosure will become apparent by describing in detail non-limiting example embodiments thereof with reference to the accompanying drawings.

FIG. 1 is a view illustrating a substrate processing device according to an embodiment of the disclosure

FIG. 2 is a view illustrating an optical system according to an embodiment of the disclosure.

FIG. 3 is a view illustrating the optical system according to an embodiment of the disclosure.

FIG. 4 is a view illustrating the optical system according to an embodiment of the disclosure.

FIG. 5 is a view illustrating the optical system according to an embodiment of the disclosure.

FIG. 6 is a flowchart illustrating a method of operating a substrate processing device according to an embodiment of the disclosure.

FIG. 7 is a flowchart illustrating a method of operating a substrate processing device according to an embodiment of the disclosure.

FIG. 8 is views illustrating the method of operating a substrate processing device according to an embodiment of the disclosure.

FIG. 9 is an enlarged view of an area S1 of FIG. 8.

FIG. 10 is views illustrating a method of operating a substrate processing device according to an embodiment of the disclosure.

FIG. 11 is an enlarged view of an area S2 of FIG. 10.

### DETAILED DESCRIPTION

Hereinafter, non-limiting example embodiments of the disclosure will be described clearly and in detail with reference to the accompanying drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

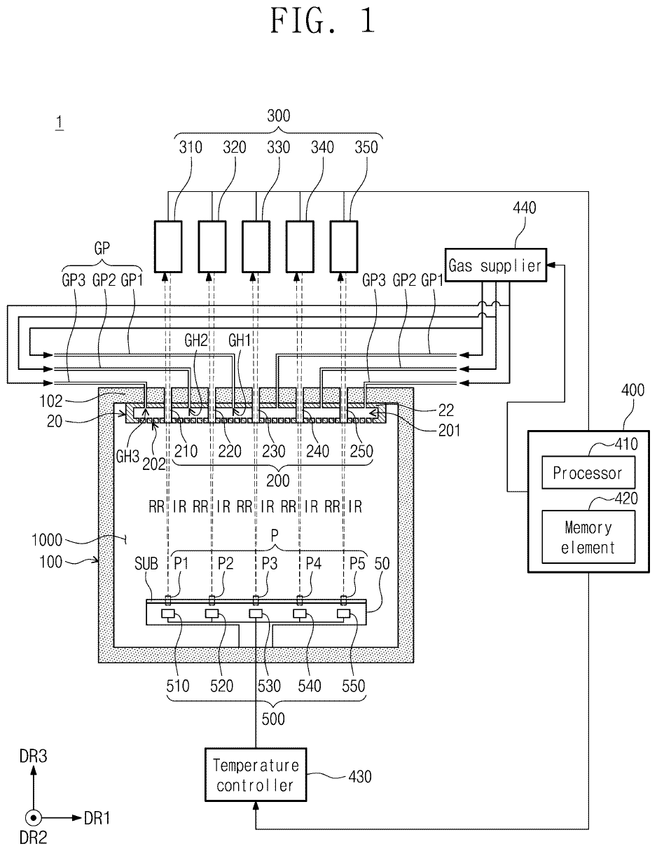

FIG. 1 is a view illustrating a substrate processing device 1 according to an embodiment of the disclosure.

Referring to FIG. 1, the substrate processing device 1 may include a chamber 100, a shower head 20 in the chamber 100, gas supply pipes GP connected to the shower head 20, a gas supplier 440 for supplying a process gas into the chamber 100 through the gas supply pipes GP, a stage 50 provided in the chamber 100, a temperature controller 430 for adjusting a temperature of the stage 50, a plurality of optical systems 300 set to irradiate incident light IR toward the stage 50, and a control system 400 for controlling an operation of the substrate processing device 1.

The chamber 100 may include a processing space 1000 defined therein. The chamber 100 may be referred to as a processing chamber. A semiconductor process may be performed inside the chamber 100. The processing space 1000 may be sealed by the chamber 100.

The stage 50 may be provided inside the processing space 1000. The stage 50 may accommodate a substrate SUB. The substrate SUB may be loaded on the stage 50. The stage 50 may include an upper surface on which the substrate SUB is loaded.

A plurality of points P may be defined on the upper surface of the stage 50 or an upper surface of the substrate SUB. The plurality of points P may include all points on the upper surface of the stage 50 and all points on the upper surface of the substrate SUB. That is, the upper surface of the stage 50 may have the plurality of points P, and the upper surface of the substrate SUB may also have the plurality of points P. Each of the points P on the upper surface of the stage 50 and each of the points P on the upper surface of the substrate SUB may vertically overlap with each other.

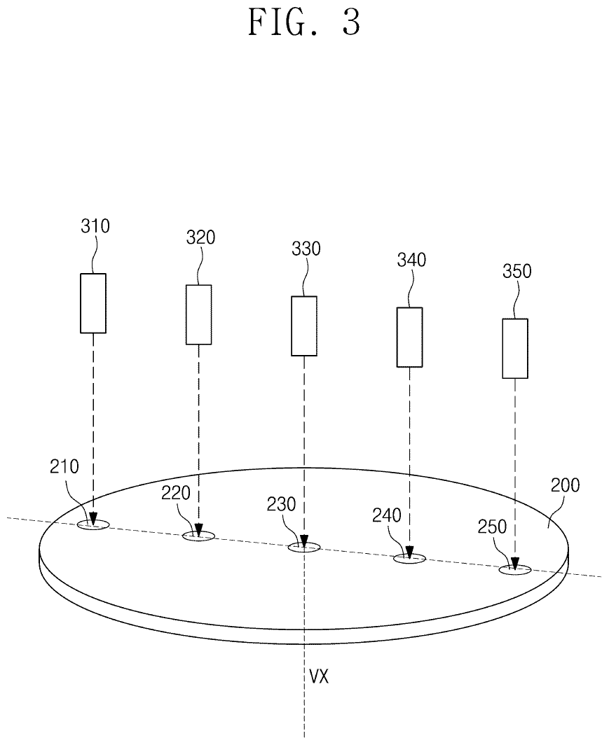

The plurality of points P may be laterally spaced apart from each other. That is, the plurality of points P may be spaced apart from each other in a first direction DR1. The plurality of points P may be spaced apart from each other in a radial direction with respect to a center of the upper surface of the stage 50. The plurality of points P may be radially arranged with respect to the center of the upper surface of the stage 50. For example, the plurality of points P may include first to fifth points P1 to P5, the third point P3 may be disposed to overlap with a virtual vertical axis VX (see FIG. 3) passing through the center of the stage 50, and the other points (e.g., the first point P1, the second point P2, the fourth point P4, and the fifth point P5) may be radially spaced apart from the virtual vertical axis VX.

The stage 50 may include a temperature adjuster 500 capable of heating or cooling the plurality of points P on the upper surface of the stage 50. That is, the temperature adjuster 500 may adjust temperatures of the points P on the upper surface of the stage 50. The temperature adjuster 500 may include a heat exchanger, a heater, a cooler, a Peltier device, and the like.

A plurality of temperature adjusters 500 may be provided under the plurality of points P on the upper surface of the stage 50. For example, first to fifth temperature adjusters 510, 520, 530, 540, and 550 may be provided below the first to fifth points P1 to P5. The first to fifth temperature adjusters 510, 520, 530, 540, and 550 may vertically overlap with the first to fifth points P1 to P5, respectively. Therefore, the first temperature adjuster 510 may heat or cool the first point P1, the second temperature adjuster 520 may heat or cool the second point P2, the third temperature adjuster 530 may heat or cool the third point P3, the fourth temperature adjuster 540 may heat or cool the fourth point P4, and the fifth temperature adjuster 550 may heat or cool the fifth point P5.

The temperature adjusters 500 may heat or cool the substrate SUB. The temperature adjusters 500 may heat or cool the points P on the upper surface of the stage 50, and the temperature adjusters 500 may indirectly heat or cool the substrate SUB through the stage 50. Accordingly, the substrate processing device 1 may adjust a temperature of the substrate SUB on which the semiconductor process is performed.

The temperature controller 430 may control the temperature adjusters 500. In detail, the temperature controller 430 may independently control the temperature adjusters 500. Therefore, the temperature adjusters 500 may operate independently of each other. In detail, the first temperature adjuster 510 may heat the first point P1, but the second temperature adjuster 520 may cool the second point P2. Therefore, the temperatures of the first to fifth points P1 to P5 may be set differently from each other. Accordingly, the substrate processing device 1 may more minutely set a process variable.

Further, the temperature controller 430 may independently operate the temperature adjusters 500. In detail, the first temperature adjuster 510 may be operated, but the second temperature adjuster 520 may not be operated.

The shower head 20 may be provided inside the processing space 1000. The process gas may be distributed into the processing space 1000 through the shower head 20. The shower head 20 may evenly supply the process gas into the processing space 1000. The shower head 20 may include a diffusion space 201 through which the process gas is introduced from the gas supply pipes GP, and a plurality of distribution holes 202 through which the process gas passes. The plurality of distribution holes 202 may allow the diffusion space 201 in the shower head 20 and the processing space 1000 in the chamber 100 to communicate with each other. The diffusion space 201 may correspond to a single space defined in the shower head 20.

The shower head 20 may be located in a ceiling portion 102 of the chamber 100. That is, the shower head 20 may be coupled to the ceiling portion 102 of the chamber 100. The shower head 20 may include a ceiling portion 22 coupled to the ceiling portion 102 of the chamber 100. The distribution holes 202 may vertically pass through a bottom surface of the shower head 20. Therefore, the processing gas in the diffusion space 201 may be evenly lowered toward the stage 50 through the distribution holes 202.

The gas supplier 440 may correspond to a storage or supply source in which the process gas is stored. The gas supplier 440 may be connected to the chamber 100 through the gas supply pipes GP. The gas supplier 440 may supply the process gas into the processing space 1000 through the gas supply pipes GP. For example, the process gas may include an oxygen gas used in an etching process.

The gas supply pipes GP may be connected to the shower head 20 while passing through the ceiling portion 102 of the chamber 100. Further, the gas supply pipes GP may be connected to the diffusion space 201 in the shower head 20 while passing through the ceiling portion 22 of the shower head 20.

The gas supply pipes GP may include a first gas supply pipe GP1 adjacent to a central portion of the diffusion space 201, a second gas supply pipe GP2 spaced apart from the first gas supply pipe GP1, and a third gas supply pipe GP3 adjacent to an edge of the diffusion space 201. The first gas supply pipe GP1, the second gas supply pipe GP2, and the third gas supply pipe GP3 may be sequentially arranged in a radial direction from the central portion of the diffusion space 201.

The first to third gas supply pipes GP1 to GP3 may have first to third supply ports GH1 to GH3 connected to the diffusion space 201, respectively. The first to third supply ports GH1 to GH3 may respectively correspond to ends of the first to third gas supply pipes GP1 to GP3. The first to third supply ports GH1 to GH3 may be laterally spaced apart from each other. In detail, the first gas supply pipe GP1 may have the first supply port GH1 connected to the diffusion space 201. The second gas supply pipe GP2 may have the second supply port GH2 connected to the diffusion space 201. The third gas supply pipe GP3 may have the third supply port GH3 connected to the diffusion space 201. The first supply port GH1 may be adjacent to the central portion of the diffusion space 201, the third supply port GH3 may be adjacent to the edge of the diffusion space 201, and the second supply port GH2 may be located between the first supply port GH1 and the third supply port GH3.

Therefore, the first gas supply pipe GP1 may intensively supply the process gas to the central portion of the diffusion space 201, the third gas supply pipe GP3 may intensively supply the process gas to the edge of the diffusion space 201, and the second gas supply pipe GP2 may intensively supply the process gas between the central portion and the edge of the diffusion space 201. Therefore, the substrate processing device 1 may minutely adjust a concentration of the process gas within the processing space 1000.

The optical systems 300 may radiate incident light IR toward the stage 50. In detail, the optical systems 300 may radiate the incident light IR toward the points P on the upper surface of the stage 50. For example, the optical systems 300 may include a first optical system 310 configured to radiate the incident light IR toward the first point P1 on the upper surface of the stage 50, a second optical system 320 configured to radiate the incident light IR toward the second point P2 on the upper surface of the stage 50, a third optical system 330 configured to radiate the incident light IR toward the third point P3 on the upper surface of the stage 50, a fourth optical system 340 configured to radiate the incident light IR toward the fourth point P4 on the upper surface of the stage 50, and a fifth optical system 350 configured to radiate the incident light IR toward the fifth point P5 on the upper surface of the stage 50.

The optical systems 300 may receive reflected light RR generated from the incident light IR. The reflected light RR may include substrate-reflected light reflected from the upper surface of the substrate SUB loaded on the stage 50. For example, the first optical system 310 may radiate the incident light IR toward the first point P1 on the upper surface of the substrate SUB and receive the reflected light RR reflected at the first point P1. Further, the second optical system 320 may radiate the incident light IR toward the second point P2 on the upper surface of the substrate SUB and receive the reflected light RR reflected at the second point P2. Further, the third optical system 330 may radiate the incident light IR toward the third point P3 on the upper surface of the substrate SUB and receive the reflected light RR reflected at the third point P3. Further, the fourth optical system 340 may radiate the incident light IR toward the fourth point P4 on the upper surface of the substrate SUB and receive the reflected light RR reflected at the fourth point P4. Further, the fifth optical system 350 may radiate the incident light IR toward the fifth point P5 on the upper surface of the substrate SUB and receive the reflected light RR reflected at the fifth point P5.

The substrate processing device 1 may further include optical passages 200 set to transmit the incident light IR and the reflected light RR. The optical passage 200 may include a material capable of transmitting light. The optical passage 200 may be referred to as an optical window or an optical lens.

The optical passages 200 may be provided over the stage 50. The optical passages 200 may be radially arranged around the virtual vertical axis VX passing through the center of the stage 50. The optical passages 200 may be laterally spaced apart from each other. The optical passages 200 may be provided over the plurality of points P. In detail, the optical passage 200 may include a first optical passage 210 provided above the first point P1, a second optical passage 220 provided above the second point P2, a third optical passage 230 provided above the third point P3, a fourth optical passage 240 provided above the fourth point P4, and a fifth optical passage 250 provided above the fifth point P5. The optical passages 200 may vertically extend.

The optical passages 200 may pass through the ceiling portion 102 of the chamber 100. Therefore, the optical passages 200 may optically connect the processing space 1000 and an outer space of the chamber 100. The optical passages 200 may pass through the shower head 20. The optical passage 200 may pass through the diffusion space 201 of the shower head 20. Therefore, the incident light IR may be incident from the optical systems 300 outside the chamber 100 to the processing space 1000 inside the chamber 100 through the optical passages 200, and the reflected light RR may be received again from the processing space 1000 inside the chamber 100 to the optical systems 300 outside the chamber 100 through the optical passages 200. Therefore, the optical systems 300 may be provided outside the chamber 100.

The control system 400 may receive optical data based on the incident light IR and the reflected light RR from the optical systems 300. The control system 400 may include a memory element 420 (also referred to as memory) that stores the received optical data and at least one processor 410 that may calculate surface data of the substrate SUB by analyzing the received optical data. The surface data of the substrate SUB may include thicknesses of one or more films formed on the upper surface of the substrate SUB or depths of recesses formed inside the substrate SUB formed through the etching process. The thicknesses of the one or more films may mean thicknesses of one or more films formed on the plurality of points P of the substrate SUB. Further, the depths of the recesses may mean depths of recesses formed at the plurality of points P of the substrate SUB. Therefore, the substrate processing device 1 may monitor process distribution of the substrate SUB using the control system 400. The process distribution may mean a deviation between results of the semiconductor process performed on the substrate SUB.

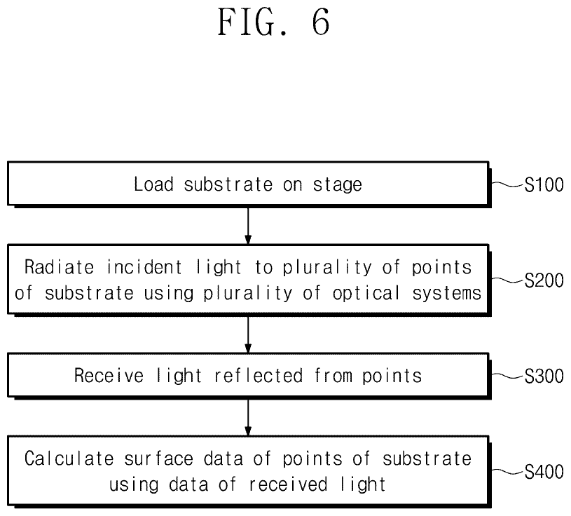

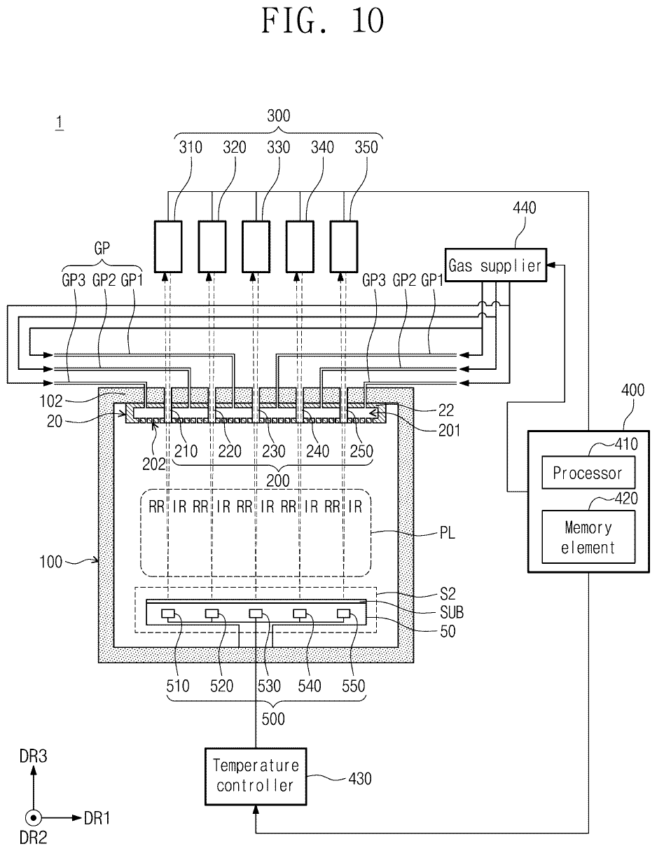

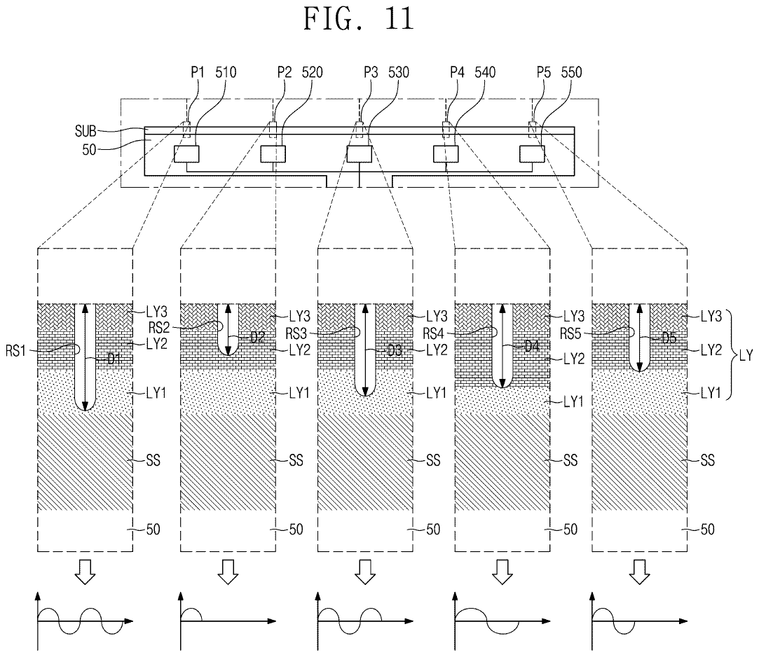

According to some embodiments of the disclosure, the memory element 420 may further include computer instructions that, when executed by the at least one processor 410, cause the control system 400 (e.g., the at least one processor 410) to perform its functions. For example, the computer instructions, when executed by the at least one processor 410, may cause the control system 400 (e.g., the at least one processor 410) to control the substrate processing device 1 to performs methods described below with reference to FIGS. 6-11.

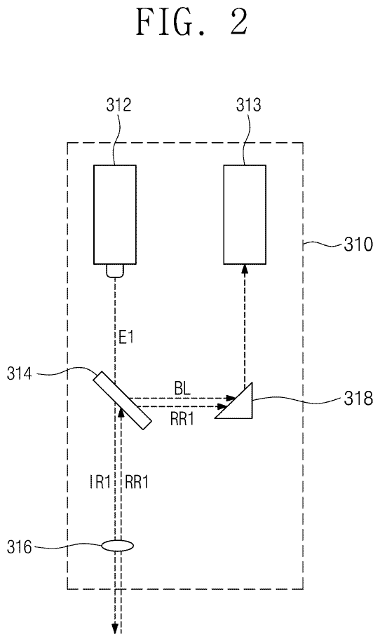

FIG. 2 is a view illustrating the optical system 300 according to an embodiment of the disclosure.

Referring to FIG. 2, each of the optical systems 300 may include a light source configured to emit light, a splitter configured to divide the light into incident light and branch light, and a spectrometer configured to receive the branch light and reflected light. For example, the first optical system 310 may include a first light source 312 configured to emit first light E1, a first splitter 314 configured to divide the first light E1 into first incident light IR1 and first branch light BL, and a first spectrometer 313 configured to receive the first branch light D1. The first incident light IR1 may be incident into the processing space 1000 through the first optical passage 210 (see FIG. 1).

The first optical system 310 may further include a first reflector 318 configured to guide the first branch light D1 to the first spectrometer 313. The first reflector 318 may redirect a traveling path of the first branch light D1 branching from the first splitter 314. For example, the first reflector 318 may include a mirror capable of reflecting the first branch light D1 branching from the first splitter 314 to the first spectrometer 313.

The first optical system 310 may further include a first lens 316 that transmits the first incident light IR1 incident on the first optical passage 210. The first lens 316 may condense the first incident light IR1. Therefore, illuminance of the first incident light IR1 incident on the first optical passage 210 may be improved. The first lens 316 may be provided between the first splitter 314 and the first optical passage 210.

First reflected light RR1 generated from the first incident light IR1 may be received by the first spectrometer 313 through the first splitter 314. The first reflected light RR1 may be generated inside the processing space 1000 by the first incident light IR1. In detail, the first reflected light RR1 may include substrate-reflected light obtained by reflecting the first incident light IR1 by the substrate SUB.

The first splitter 314 may redirect a traveling path of the first reflected light RR1. The first splitter 314 may guide the first reflected light RR1 to the first spectrometer 313. Therefore, the first spectrometer 313 may further receive the first reflected light RR1.

In the embodiment, the first splitter 314 may guide the first reflected light RR1 to the first reflector 318, and the first reflector 318 may reflect the first reflected light RR1 to the first spectrometer 313. Therefore, the first reflected light RR1 may be received by the first spectrometer 313.

The second optical system 320, the third optical system 330, the fourth optical system 340, and the fifth optical system 350 may have substantially the same structure as the structure of the first optical system 310. That is, components of the second optical system 320, the third optical system 330, the fourth optical system 340, and the fifth optical system 350 and materials constituting the same may be substantially the same as components and materials of the first optical system 310. Thus, for convenience of description, descriptions of the second optical system 320, the third optical system 330, the fourth optical system 340, and the fifth optical system 350 may be understood from the description of the first optical system 310.

FIG. 3 is a view illustrating the optical system 300 according to an embodiment of the disclosure.

Referring to FIG. 3, the first to fifth optical passages 210, 220, 230, 240, and 250 may be arranged in a line. The first to fifth optical passages 210, 220, 230, 240, and 250 may be arranged on one virtual horizontal line perpendicular to the virtual vertical axis VX passing through the center of the stage 50 and may be laterally spaced apart from each other.

The first to fifth optical systems 310, 320, 330, 340, and 350 may radiate incident light into the processing space 1000 through the first to fifth optical passages 210, 220, 230, 240, and 250, respectively, and receive reflected light that is reflected inside the processing space 1000.

Therefore, the optical systems 300 may radiate incident light to the plurality of points P of the substrate SUB loaded on the stage 50 and receive reflected light reflected at the plurality of points P.

Accordingly, the substrate processing device 1 may calculate surface data at the plurality of points P of the substrate SUB based on the optical data.

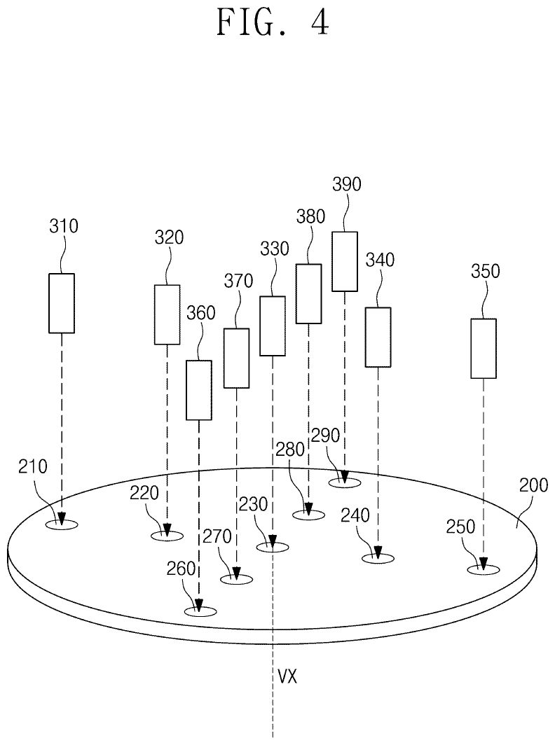

FIG. 4 is a view illustrating the optical system 300 according to an embodiment of the disclosure.

Referring to FIG. 4, the optical system 300 may further include a sixth optical system 360, a seventh optical system 370, an eighth optical system 380, a ninth optical system 390. Likewise, the optical passage 200 may further include a sixth optical passage 260, a seventh optical passage 270, an eighth optical passage 280, and a ninth optical passage 290. The sixth optical passage 260, the seventh optical passage 270, the eighth optical passage 280, and the ninth optical passage 290 may be arranged on another virtual horizontal line perpendicular to the virtual vertical axis VX passing through the center of the stage 50. The other virtual horizontal line may be perpendicular to the one virtual horizontal line. That is, the optical passages 200 may be arranged in a cross shape on a plane.

The first to ninth optical systems 310, 320, 330, 340, 350, 360, 370, 380, and 390 may radiate incident light into the processing space 1000 through the first to ninth optical passages 210, 220, 230, 240, 250, 260, 270, 280, and 290, respectively, and receive reflected light that is reflected inside the processing space 1000.

Therefore, the optical systems 300 may radiate the incident light to the plurality of points P of the substrate SUB loaded on the stage 50 and receive the reflected light reflected at the plurality of points P.

Accordingly, the substrate processing device 1 may calculate the surface data of the substrate SUB having high reliability based on the optical data.

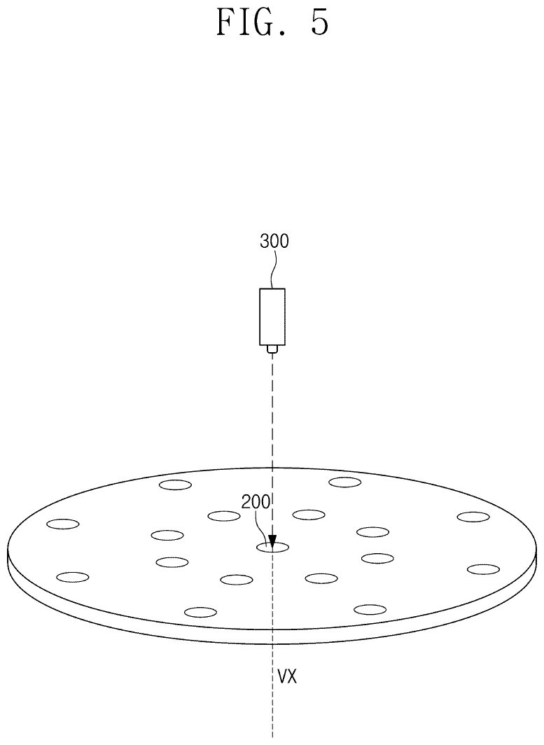

FIG. 5 is a view illustrating the optical system 300 according to an embodiment of the disclosure.

Referring to FIG. 5, the optical passages 200 may be radially arranged inside the ceiling portion 102 of the chamber 100 around the virtual vertical axis VX passing through the center of the stage 50. For example, the optical passages 200 may be arranged with respect to each other in at least one circle around the virtual vertical axis VX. The optical systems 300 may radiate the incident light into the processing space 1000 through the optical passages 200, respectively, and receive the reflected light that is reflected inside the processing space 1000.

Accordingly, the substrate processing device 1 may calculate the surface data of the substrate SUB having higher reliability based on the optical data.

FIG. 6 is a flowchart illustrating a method of operating the substrate processing device 1 according to an embodiment of the disclosure.

Referring to FIG. 6, a method (hereinafter, referred to as an “operating method”) of operating the substrate processing device 1 may include an operation S100 of loading a substrate on a stage, an operation S200 of radiating incident light to a plurality of points of the substrate using a plurality of optical systems, an operation S300 of receiving light reflected from the points, and an operation S400 of calculating surface data at the points of the substrate using data of the received light.

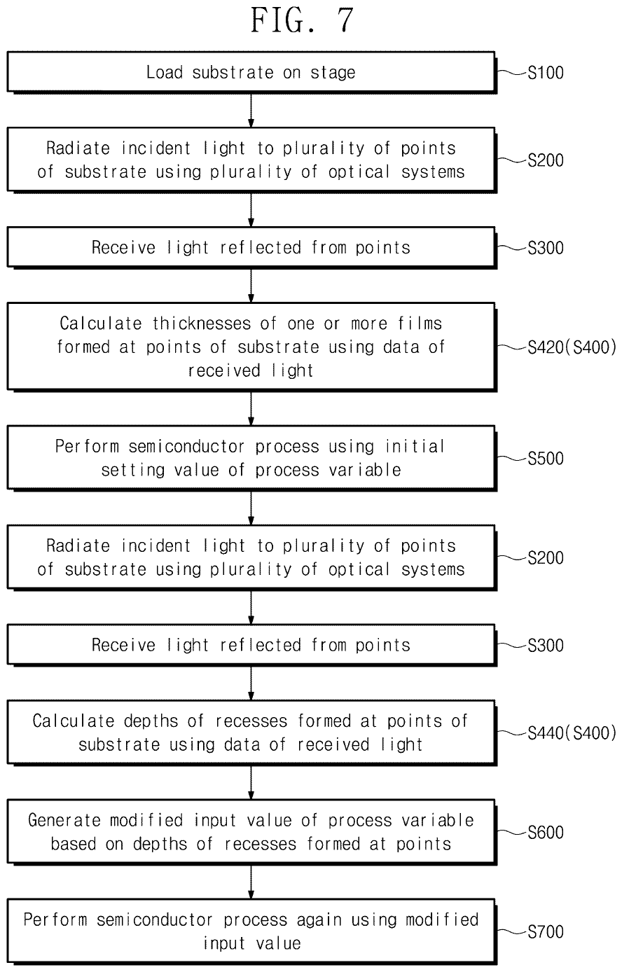

FIG. 7 is a flowchart illustrating a method of operating the substrate processing device 1 according to an embodiment of the disclosure.

Referring to FIG. 7, the operating method may further include an operation S500 of performing a semiconductor process on the substrate, an operation S600 of generating a modified input value of a process variable, and an operation S700 of again performing the semiconductor process using the modified input value.

Referring to FIGS. 6 and 7, in the operation S400 of calculating surface data at the points of the substrate using the data of the received light, the surface data may include thicknesses of one or more films formed at the points of the substrate. Furthermore, the surface data may include depths of recesses formed at the points of the substrate. In other words, the operation S400 of calculating the surface data at the points of the substrate using the data of the received light may include an operation S420 of calculating the thicknesses of one or more films formed at the points of the substrate using the data of the received light, and an operation S440 of calculating the depths of the recesses formed at the points of the substrate using the data of the received light.

The operation S420 of calculating the thicknesses of the one or more films formed at the points of the substrate using the data of the received light may be an operation of obtaining initial surface data of the substrate. That is, the substrate processing device may obtain the initial surface data of the substrate to calculate a more accurate process distribution. To this end, the operation S420 may be performed before the operation S500 of performing the semiconductor process. The operation S420 may be based on optical data obtained by radiating the incident light to the plurality of points of the substrate using the plurality of optical systems and receiving the reflected light reflected from the points.

The operation S440 of calculating the depths of the recesses formed at the points of the substrate using the data of the received light may be performed after the operation S500 of performing the semiconductor process. That is, the operation S440 may be an operation for obtaining the surface data of the substrate on which the semiconductor process is performed. Therefore, result data of the semiconductor process performed on the substrate may be obtained. Likewise, the operation S440 may be based on optical data obtained by radiating the incident light to the plurality of points of the substrate using the plurality of optical systems and receiving the reflected light reflected from the points.

Further, the operation S440 of calculating the depths of the recesses formed at the points of the substrate using the data of the received light may be performed in real time while the operation S500 of performing the semiconductor process is performed. That is, operation S200 of radiating the incident light to the plurality of points of the substrate using the plurality of optical systems, and the operation S300 of receiving reflected light reflected from the points may be performed in real time while the operation S500 of performing the semiconductor process is performed. Therefore, the substrate processing device may monitor a progress situation of the semiconductor process in real time.

The operation S500 of performing the semiconductor process may be performed using an initial setting value of the process variable. The process variable may include at least one from among a process temperature, a supply rate of a process gas, an amount of process results formed per unit process temperature, and an amount of process results formed per unit supply rate of the process gas. For example, the semiconductor process may include the etching process, and the process variable may include at least one from among an etching temperature, a supply rate of an etching gas, an etching depth per unit etching temperature, and an etching depth per unit supply rate of the etching gas. In detail, the etching temperature may be a set temperature of the temperature adjuster, and a unit thereof may correspond to Celsius. Further, the supply rate of the etching gas may be a supply rate of the etching gas supplied to the processing space through the gas supply pipe, and a unit thereof may correspond to sccm. Further, the etching depth per unit etching temperature may mean how much the etching depth increases when the set temperature of the temperature adjuster increases by 1 degree. Further, the etching depth of the etching gas per unit supply rate may mean how much the etching depth further increases when the supply rate of the etching gas increases by 1 sccm.

It may be required to set initial input values of process variables to perform the semiconductor process. Accordingly, the initial input values of the process variables may be input by an operator or may be determined (e.g., by the at least one processor 410) as a preset value.

When the surface data of the substrate on which the semiconductor process is performed is calculated, the modified input value of the process variable may be generated. That is, the substrate processing device may adjust the process variables so that a desired process distribution may be achieved based on the surface data of the substrate on which the semiconductor process is performed. For example, the etching temperature may increase or the supply rate of the etching gas may increase, to increase the etching depth of the substrate based on the surface data of the substrate on which the etching process is performed. In contrast, the etching temperature may decrease or the supply rate of the etching gas may decrease, to decrease the etching depth of the substrate SUB. Therefore, the substrate processing device may generate the modified input value.

The substrate processing device may perform the semiconductor process again using the modified input value. Therefore, the substrate processing device may obtain a process result in which the process dispersion is reduced.

In the embodiment, the substrate processing device may calculate surface data of a new substrate on which the semiconductor process is performed again and adjust the process variables again based on the calculated surface data. That is, the substrate processing device may generate the modified input value of the process variable, repeatedly perform the semiconductor process using the modified input value, and thus generate final process variables for obtaining optimum results.

Accordingly, a substrate processing device having improved process distribution and a method of operating the same may be provided.

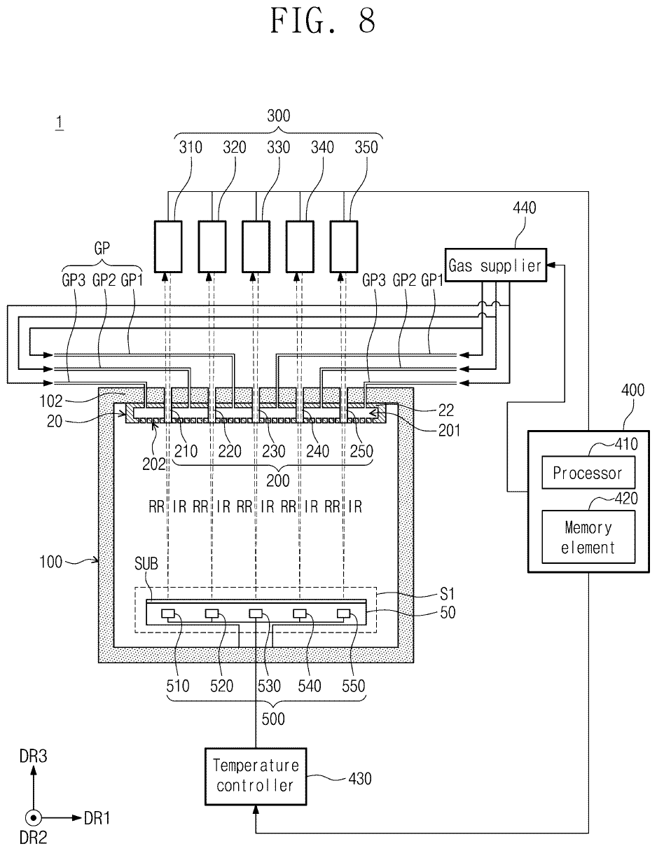

FIGS. 8 to 11 are views illustrating a method of operating the substrate processing device 1 according to an embodiment of the disclosure.

Referring to FIGS. 7, 8, and 9, the substrate SUB may be loaded on the stage 50. The plurality of optical systems 300 may radiate the incident light IR onto the substrate SUB through the optical passages 200. In detail, the first to fifth optical systems 310, 320, 330, 340, and 350 may radiate the incident light IR toward the first to fifth points P1, P2, P3, P3, and P5 of the substrate SUB through the first to fifth optical passages 210, 220, 230, 240, and 250, respectively. For example, the first optical system 310 may radiate the first incident light IR1 toward the first point P1 of the substrate SUB through the first optical passage 210, the second optical system 320 may radiate second incident light IR2 toward the second point P2 of the substrate SUB through the second optical passage 220, the third optical system 330 may radiate third incident light IR3 toward the third point P3 of the substrate SUB through the third optical passage 230, the fourth optical system 340 may radiate fourth incident light IR4 toward the fourth point P4 of the substrate SUB through the fourth optical passage 240, and the fifth optical system 350 may radiate fifth incident light IR5 toward the fifth point P5 of the substrate SUB through the fifth optical passage 250.

The substrate SUB may include a semiconductor substrate SS and at least one film LY laminated on the semiconductor substrate SS. The incident light IR may be reflected at an interface between the semiconductor substrate SS and the at least one film LY. Further, the incident light IR may be reflected at interfaces between the plurality of films LY laminated on the semiconductor substrate SS. For example, the substrate SUB may include the semiconductor substrate SS, and a first film LY1, a second film LY2, and a third film LY3 sequentially laminated on the semiconductor substrate SS. A portion of the first incident light IR1 may sequentially pass through the first to third films LY1, LY2, and LY3 and the semiconductor substrate SS from an upper side of the substrate SUB. Transmittance of the first incident light IR1 may gradually decrease toward a lower side of the substrate SUB. A portion of the passing first incident light IR1 may be reflected at an interface between the third film LY3 and the second film LY2, an interface between the second film LY2 and the first film LY1, an interface between the first film LY1 and the semiconductor substrate SS, and an interface between the semiconductor substrate SS and the stage 50. The other portion of the first incident light IR1 may be reflected from a surface (e.g., upper surface) of the third film LY3. The passage and reflection mechanism may also be applied to the second incident light IR2, the third incident light IR3, the fourth incident light IR4, and the fifth incident light IR5.

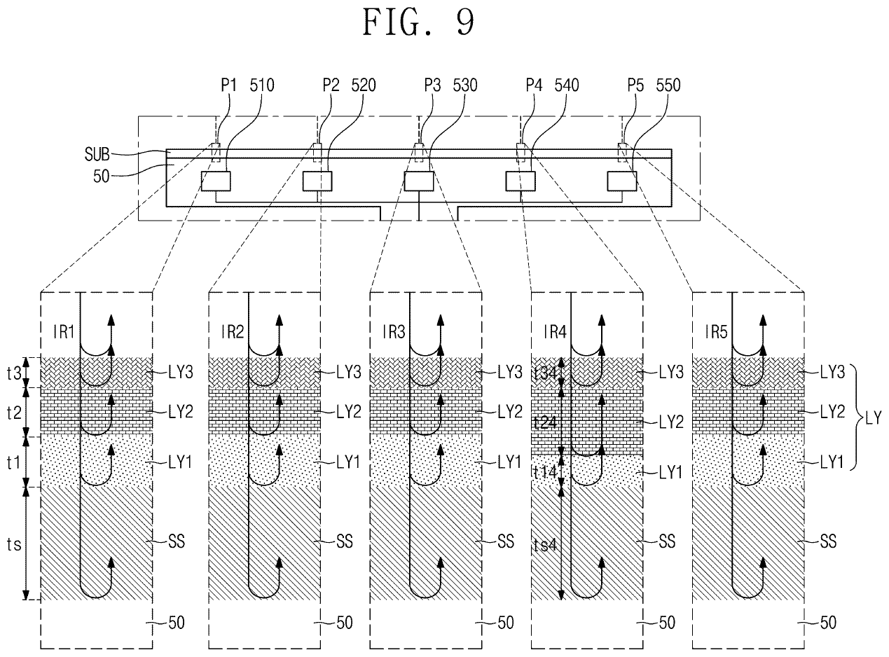

The first optical system 310 may receive reflected light generated from the first incident light IR1 through the first optical passage 210. Therefore, the first optical system 310 may collect optical data at the first point P1 of the substrate SUB. The control system 400 may receive the optical data from the first optical system 310 and calculate the surface data of the substrate SUB. That is, the control system 400 may calculate a thickness ts of the semiconductor substrate SS and firth to third thicknesses t1, t2, and t3 of the first film LY1, the second film LY2, and the third film LY3, respectively, which correspond to the first point P1. Likewise, the control system 400 may receive optical data from the second optical system 320, the third optical system 330, the fourth optical system 340, and the fifth optical system 350, and calculate the thickness of the semiconductor substrate SS and the thicknesses of the first film LY1, the second film LY2, and the third film LY3, which correspond to the second point P2, the third point P3, the fourth point P4, and the fifth point P5. As an example, FIG. 9 shows that, at the fourth point P4, the first film LY1 may include a first thickness t14, the second film LY2 may include a second thickness t24, the third film LY3 may include a third thickness t34, and the semiconductor substrate SS may include a fourth thickness ts4.

Accordingly, the control system 400 may obtain the initial surface data of the substrate SUB at each point P. For example, the control system 400 may obtain the initial surface data of the substrate SUB, which indicates that the first thickness t14 of the first film LY1 at the fourth point P4 is smaller than first thicknesses t1 of the first film LY1 at the other points P and the second thickness t24 of the second film LY2 at the fourth point P4 is greater than second thicknesses t2 of the second film LY2 at the other points P. The substrate processing device 1 may set the process variable of the fourth point P4 to be different from the process variables of the other points P according to the initial surface data of the substrate SUB.

Referring to FIGS. 7, 10, and 11, the semiconductor process may be performed using the initial setting value of the process variable. The semiconductor process may include the etching process. For example, the etching process may include a plasma etching process, and plasma PL including etching ions may be formed inside chamber 100.

The initial setting value of the process variable may be input by the operator and stored in the memory element 420. For example, the semiconductor process may be performed using the input initial etching temperature and the initial supply rate of the etching gas.

The optical systems 300 may radiate the incident light IR to the points P of the substrate SUB in real time through the optical passages 200 while the semiconductor process is performed. The incident light IR may be reflected at the points P of the substrate SUB on which the process is performed. The optical systems 300 may receive the reflected light RR reflected at the points P of the substrate SUB through the optical passages 200.

The first optical system 310, the second optical system 320, the third optical system 330, the fourth optical system 340, and the fifth optical system 350 may collect the optical data at the first point P1, the second point P2, the third point P3, the fourth point P4, and the fifth point P5, respectively. The control system 400 may receive the optical data from the first optical system 310, the second optical system 320, the third optical system 330, the fourth optical system 340, and the fifth optical system 350 and calculate the surface data of the substrate SUB. That is, the control system 400 may calculate first to fifth depths D1 to D5 of first to fifth recesses RS1 to RS5 at the first to fifth points P1 to P5, respectively.

In detail, the optical data may include interference waves generated through an interference between the received light. The control system 400 may calculate the thicknesses of the films LY and the first to fifth depths D1 to D5 of the first to fifth recesses RS1 to RS5 formed on the semiconductor substrate SS based on a wavelength, an amplitude, and a shape of the interference waves. For example, the third recess R3 at the third point P3 may be utilized as a reference recess, and the interference waves obtained through the third optical system 330 may be utilized as reference waves. A total number of crests and troughs of interference waves obtained through the first optical system 310 may be generated such as to be about ⅓ greater than a total number of crests and troughs of the reference waves, and thus the control system 400 may calculate (or determine) a result that the etching process is excessively performed at the first point P1. Further, a total number of crests and troughs of interference waves obtained through the second optical system 320 may be generated such as to be only about ⅓ the total number of crests and troughs of the reference waves, and thus the control system 400 may calculate (or determine) a result that the etching process is incompletely performed at the second point P2. Further, the total number of crests and troughs of interference waves obtained through the fifth optical system 350 may be generated such as to be only about ⅔ the total number of crests and troughs of the reference waves and thus the control system 400 may calculate (or determine) a result that the etching process is incompletely performed at the fifth point P5. Further, a total number of crests and troughs of the interference waves obtained through the fourth optical system 340 may be generated such as to be only about ⅔ the total number of crests and troughs of the reference waves, but a wavelength of such interference waves may be about 1.2 times greater than a wavelength of the reference waves, and thus the control system 400 may calculate (or determine) a result that a thickness of the film LY at the fourth point P4 is different from a thickness of the film LY at the third point P3 and the etching process is incompletely performed.

Accordingly, the control system 400 may calculate (or determine) the degree of performance of the etching process at each point P in real time while the etching process is performed.

The control system 400 may generate the modified input value of the process variable based on the first to fifth depths D1 to D5 of the recesses RS1 to RS5 formed at the points P. For example, the control system 400 may increase the etching temperature, through the temperature controller 430, at the second point P2, the fourth point P4, and the fifth point P5 at which the etching process is calculated (or determined) to be incompletely performed. Further, the control system 400 may decrease the etching temperature, through the temperature controller 430, at the first point P1 at which the etching process is calculated (or determined) to be excessively performed. Further, the control system 400 may maintain the etching temperature, through the temperature controller 430, at the third point P3 at which the etching process is calculated (or determined) to be performed with a desired level.

In the embodiment, the control system 400 may increase a supply rate of the second gas supply pipe GP2 through which the etching gas is intensively supplied to the second point P2 and the fourth point P4 through the gas supplier 440.

The substrate processing device 1 may perform the semiconductor process again using the modified input value. That is, the substrate processing device 1 may perform the semiconductor process on a new substrate SUB again by adjusting the process variables for the first point P1, the second point P2, the fourth point P4, and the fifth point P5.

Accordingly, the substrate processing device 1 may repeatedly perform the operation S500 of performing the semiconductor process and the operation S600 of generating the modified input values of the process variables, to improve the process distribution in stages.

According to an embodiment of the disclosure, a method of operating a substrate processing device may include: providing a substrate on a stage; radiating, by optical systems of the substrate processing device, incident light to points of the substrate; receiving, by the optical systems, reflected light from the points, the reflected light being generated from the incident light; and calculating, by a control system of the substrate processing device, surface data of the points of the substrate based on data of the reflected light that is received.

According to an embodiment of the disclosure, the method may further include: performing, by the substrate processing device, a semiconductor process on the substrate or another substrate.

According to an embodiment of the disclosure, the radiating the incident light, the receiving the reflected light, and the calculating the surface data of the points may be performed before the performing the semiconductor process.

According to an embodiment of the disclosure, the method may further include: the substrate includes one or more films, and wherein the surface data may include thicknesses of the one or more films at the points.

According to an embodiment of the disclosure, the performing the semiconductor process may include performing the semiconductor process using an initial input value of a process variable, and wherein the method may further include: generating, by the control system, a modified input value of the process variable based on the surface data of the points that is calculated; and performing the semiconductor process again using the modified input value.

According to an embodiment of the disclosure, the process variable may include at least one from among an etching temperature, a supply rate of an etching gas, an etching depth per unit etching temperature, and an etching depth per unit supply rate of the etching gas.

According to an embodiment of the disclosure, the radiating the incident light, the receiving the reflected light, and the calculating the surface data of the points may be performed in real time while performing the semiconductor process.

According to an embodiment of the disclosure, a substrate processing device may monitor a progress state of a process at a plurality of points of a substrate through a plurality of optical systems configured to radiate incident light toward a plurality of points on an upper surface of a stage and configured to receive reflected light generated from the incident light. Further, process distribution of the substrate may be identified.

Further, according to embodiments of the disclosure, a plurality of optical passages may be radially arranged around a virtual vertical axis passing through a center of a stage, and thus a substrate processing device may identify a highly reliable process distribution.

Further, according to embodiments of the disclosure, a plurality of optical systems may be compatible with a shower head through a plurality of optical passages passing through the shower head and a ceiling portion of a chamber. Further, a substrate processing device may monitor a surface state of a substrate in real time during a semiconductor process.

Further, according to embodiments of the disclosure, a substrate processing device may include a plurality of temperature adjusters set to heat or cool a plurality of points and thus may finely adjust a temperature at each point of a substrate so as to improve a process variable.

Further, according to embodiments of the disclosure, a substrate processing device may include a controller configured to calculate surface data of corresponding to a plurality of points of a substrate based on collected optical data and thus may monitor a surface state and process distribution of the substrate.

Further, according to embodiments of the disclosure, a substrate processing device may calculate initial surface data of a substrate before a semiconductor process is performed, and thus may adjust a process variable for each point so as to improve process distribution. That is, the substrate processing device may create a process environment suitable for each point.

Further, according to embodiments of the disclosure, a substrate processing device may repeatedly modify a process variable based on calculated process distribution data so as to improve process distribution. That is, the substrate processing device may repeatedly modify the process variable to calculate a uniform process result for each point.

Non-limiting example embodiments of the disclosure have been described above with reference to the accompanying drawings. In addition to the above-described embodiments, the disclosure also includes variations, modifications, and equivalents of the above-described embodiments. Further, the disclosure also includes methods implemented based on the embodiments, and variations, modifications, and equivalents of the embodiments. Thus, the scope of the disclosure should not be limited to the above-described embodiments.

What is claimed is:

1. A substrate processing device comprising:
a chamber including a processing space;
a stage inside the processing space, the stage configured to have a substrate thereon, and an upper surface of the stage comprises points that are spaced apart from each other; and
optical systems configured to respectively radiate incident light toward the points on the upper surface of the stage, while the substrate is on the stage, and receive reflected light generated from the incident light.

2. The substrate processing device of claim 1, wherein each of the optical systems comprises:
a light source configured to emit light;
a splitter configured to divide the light into the incident light and branch light; and
a spectrometer configured to receive the branch light.

3. The substrate processing device of claim 2, wherein the splitter is configured to guide the reflected light to the spectrometer, and
wherein the spectrometer is configured to receive the reflected light.

4. The substrate processing device of claim 1, further comprising:
optical passages passing through a ceiling portion of the chamber, the optical passages being laterally spaced apart from each other,
wherein the optical passages are configured to transmit the incident light and the reflected light.

5. The substrate processing device of claim 4, wherein the optical passages are radially arranged with respect to each other around a virtual vertical axis passing through a center of the stage.

6. The substrate processing device of claim 4, further comprising:
a shower head inside the chamber, the shower head including distribution holes, the distribution holes configured to distribute a process gas,
wherein the optical passages pass through the shower head and the ceiling portion of the chamber.

7. The substrate processing device of claim 6, further comprising:
gas supply pipes passing through the ceiling portion of the chamber and a ceiling portion of the shower head, the gas supply pipes connected to a diffusion space inside the shower head,
wherein the gas supply pipes comprise supply ports adjacent to the diffusion space, and
wherein the supply ports are laterally spaced apart from each other.

8. The substrate processing device of claim 1, wherein the stage comprises:
temperature adjusters laterally spaced apart from each other, the temperature adjusters configured to heat or cool the points.

9. The substrate processing device of claim 1, further comprising a control system configured to:
receive optical data based on the reflected light received by the optical systems; and
calculate surface data of the substrate corresponding to the points based on the optical data.

10. The substrate processing device of claim 9, wherein the control system is further configured to calculate:
thicknesses, at the points, of one or more films of the substrate based on the optical data; or
depths of recesses of the substrate based on the optical data, the recesses being at the points.

11. A substrate processing device comprising:
a chamber including a processing space;
a stage inside the processing space, the stage configured to have a substrate thereon;
optical passages above the stage, the optical passages being laterally spaced apart from each other; and
optical systems configured to:
radiate incident light into the processing space through the optical passages; and
receive, through the optical passages, reflected light generated inside the processing space based on the incident light.

12. The substrate processing device of claim 11, wherein each of the optical systems comprise:
a light source configured to emit light;
a splitter configured to divide the light into the incident light and branch light; and
a spectrometer configured to receive the branch light and the reflected light.

13. The substrate processing device of claim 12, further comprising:
a control system configured to receive optical data from the spectrometer and calculate surface data of the substrate based on the optical data.

14. A substrate processing device comprising:
a stage configured to have a substrate thereon;
optical systems configured to respectively radiate incident light toward points on an upper surface of the substrate on the stage, and receive reflected light generated from the incident light; and
a control system configured to calculate surface data of the points of the substrate based on the reflected light.

15. The substrate processing device of claim 14, wherein the control system is further configured to control the substrate processing device to perform a semiconductor process on the substrate or an additional substrate.

16. The substrate processing device of claim 15, wherein the control system is further configured to perform the semiconductor process on the additional substrate based on the surface data.

17. The substrate processing device of claim 14, wherein the surface data comprises thicknesses of one or more films of the substrate at the points.

18. The substrate processing device of claim 14, wherein the control system is further configured to:
control the substrate processing device to perform a semiconductor process on the substrate using an initial input value of a process variable;
generating, a modified input value of the process variable based on the surface data of the points that is calculated; and
control the substrate processing device to perform the semiconductor process on an additional substrate using the modified input value.

19. The substrate processing device of claim 18, wherein the process variable includes at least one from among an etching temperature, a supply rate of an etching gas, an etching depth per unit etching temperature, and an etching depth per unit supply rate of the etching gas.

20. The substrate processing device of claim 15, wherein the control system is further configured to perform the semiconductor process and calculate the surface data while the optical systems radiate the incident light toward the points of the substrate and receive the reflected light generated from the incident light.
